(19) United States
(12) Patent Application Publication
(10) Pub. No.: US 2026/0076079 A1
(43) Pub. Date: Mar. 12, 2026

(54) COVER WINDOW, DISPLAY DEVICE INCLUDING THE COVER WINDOW, AND ELECTRONIC APPARATUS INCLUDING THE DISPLAY DEVICE

(71) Applicant: SAMSUNG DISPLAY CO., LTD., Yongin-si (KR)

(72) Inventors: JUYOUNG YOON, Yongin-si (KR); HYUN-HYANG KIM, Yongin-si (KR); DAHYE KIM, Yongin-si (KR)

(21) Appl. No.: 19/219,176

(22) Filed: May 27, 2025

(30) Foreign Application Priority Data
Sep. 6, 2024 (KR) 10-2024-0121275

(51) Int. Cl. H10K 59/80; G02B 1/11

(52) U.S. Cl. CPC H10K 59/8791; G02B 1/11; H10K 59/873

(57) ABSTRACT

A cover window includes a base layer, an anti-reflection layer disposed on the base layer, and a nitrogen-containing layer disposed on the anti-reflection layer. The anti-reflection layer includes a high-refractive-index layer and a low-refractive-index layer disposed on the high-refractive-index layer. The nitrogen-containing layer has a thickness within a range of about 0.5 nm to about 5 nm, inclusive. Therefore, the cover window may have improved hardness and scratch resistance while exhibiting excellent reflectance.

### CROSS-REFERENCE TO RELATED APPLICATIONS

This U.S. non-provisional patent application claims priority under 35 U.S.C. § 119 to Korean Patent Application No. 10-2024-0121275, filed on Sep. 6, 2024, the entire contents of which are hereby incorporated by reference.

### TECHNICAL FIELD

The present disclosure relates to a cover window and, more specifically, to a cover window including a nitrogen-containing layer, a display device including the cover window, and an electronic apparatus including the display device.

### DISCUSSION OF THE RELATED ART

Various electronic devices such as a televisions, mobile phones, tablet computers, and portable game consoles are being developed. These electronic devices include a display panel which generates images and, in the case of a touch-sensitive display panel, detects inputs. The display panel generally includes a plurality of different layers, each having different refractive indices so as to improve display quality. A layer having a low refractive index may increase display quality by lowering reflectance, however, such layers may be comparatively soft and therefore may be prone to being easily scratched.

### SUMMARY

A cover window includes a base layer. An anti-reflection layer is disposed on the base layer and includes a high-refractive-index layer and a low-refractive-index layer disposed on the high-refractive-index layer. A nitrogen-containing layer is disposed on the anti-reflection layer and has a thickness within a range of about 0.5 nm to about 5 nm.

A refractive index of the nitrogen-containing layer may be greater than a refractive index of the low-refractive-index layer.

A refractive index of the nitrogen-containing layer may be less than a refractive index of the high-refractive-index layer.

The nitrogen-containing layer may be directly disposed on the low-refractive-index layer.

A thickness of the nitrogen-containing layer may be less than a thickness of the high-refractive-index layer, and a thickness of the low-refractive-index layer.

The low-refractive-index layer may include at least one of silicon oxide, aluminum oxide, and silicon oxynitride.

Nitrogen of the nitrogen-containing layer may be chemically bonded to a material of the low-refractive-index layer.

The cover window may further include a functional layer disposed on the nitrogen-containing layer. The functional layer may include at least one of an antistatic agent, a hard coating agent, and an anti-fingerprint agent.

A thickness of the nitrogen-containing layer may be less than a thickness of the functional layer.

The high-refractive-index layer and the low-refractive-index layer may each be provided in plural, and members of the plurality of high-refractive-index layers and members of the plurality of low-refractive-index layers may be alternately disposed with respect to each other.

A display device includes a display panel including a light-emitting element. A cover window is disposed on the display panel. The cover window includes a base layer, an anti-reflection layer disposed on the base layer and including a high-refractive-index layer and a low-refractive-index layer disposed on the high-refractive-index layer, and a nitrogen-containing layer disposed on the anti-reflection layer and having a thickness within a range of about 0.5 nm to about 5 nm, inclusive.

A refractive index of the nitrogen-containing layer may be greater than a refractive index of the low-refractive-index layer.

A refractive index of the nitrogen-containing layer may be less than a refractive index of the high-refractive-index layer.

The nitrogen-containing layer may be directly disposed on the low-refractive-index layer.

A thickness of the nitrogen-containing layer may be less than each of a thickness of the high-refractive-index layer and a thickness of the low-refractive-index layer.

The low-refractive-index layer may include at least one of silicon oxide, aluminum oxide, and silicon oxynitride.

The high-refractive-index layer and the low-refractive-index layer may each be provided in plural, and members of the plurality of high-refractive-index layers and members of the plurality of low-refractive-index layers may be alternately disposed with respect to each other.

The light-emitting element may include a first electrode, a second electrode disposed on the first electrode, and a light-emitting layer disposed between the first electrode and the second electrode.

An electronic apparatus includes a display device having a module region defined therein. An electronic module is disposed in the module region. The display device includes a display panel including a light-emitting element, and a cover window disposed on the display panel. The cover window includes a base layer, an anti-reflection layer disposed on the base layer and including a high-refractive-index layer and a low-refractive-index layer disposed on the high-refractive-index layer, and a nitrogen-containing layer disposed on the anti-reflection layer and having a thickness within a range of about 0.5 nm to about 5 nm, inclusive.

A refractive index of the nitrogen-containing layer may be greater than a refractive index of the low-refractive-index layer, and may be less than a refractive index of the high-refractive-index layer.

The nitrogen-containing layer may be directly disposed on the low-refractive-index layer.

The low-refractive-index layer may include at least one of silicon oxide, aluminum oxide, and silicon oxynitride.

A thickness of the nitrogen-containing layer may be less than each of a thickness of the high-refractive-index layer and a thickness of the low-refractive-index layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view illustrating an electronic apparatus according to an embodiment;

FIG. 2 is an exploded perspective view illustrating an electronic apparatus according to an embodiment;

FIG. 3 is a cross-sectional view illustrating a portion taken along line I-I′ of FIG. 2;

FIG. 4 is a cross-sectional view illustrating a part of an electronic apparatus according to an embodiment;

FIG. 5 is a cross-sectional view illustrating a part of an electronic apparatus according to an embodiment;

FIG. 6A is a perspective view illustrating an electronic apparatus according to an embodiment;

FIG. 6B is a perspective view illustrating an electronic apparatus according to an embodiment;

FIG. 6C is a plan view illustrating an electronic apparatus according to an embodiment;

FIG. 6D is a perspective view illustrating an electronic apparatus according to an embodiment;

FIG. 7 is an exploded perspective view illustrating an electronic apparatus according to an embodiment;

FIG. 8 is a diagram illustrating an electronic device according to an embodiment of the present invention; and

FIG. 9 is a view illustrating electronic apparatuses according to various embodiments.

### DETAILED DESCRIPTION

The inventive concept may be implemented in various modifications and have various forms, and specific embodiments are illustrated in the drawings and described in detail in the text. It is to be understood, however, that the inventive concept is not necessarily intended to be limited to the particular forms disclosed and is intended to cover all modifications, equivalents, and alternatives falling within the spirit and scope of the inventive concept.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

When an element is said to be “about” equal to a particular value, this may mean that the element is within 10% of that value, 5% of that value, 2% of that value, 1% of that value, or within 0.1% of that value.

Like reference numerals or symbols may refer to like elements throughout the specification and the figures. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. The term “and/or” includes all combinations of one or more of the associated listed elements.

Although the terms first, second, etc., may be used to describe various elements, these elements should not necessarily be limited by these terms. These terms are used to distinguish one element from another element. For example, a first element may be referred to as a second element, and similarly, a second element may also be referred to as a first element without departing from the scope of the inventive concept. The singular forms include the plural forms as well, unless the context clearly indicates otherwise.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

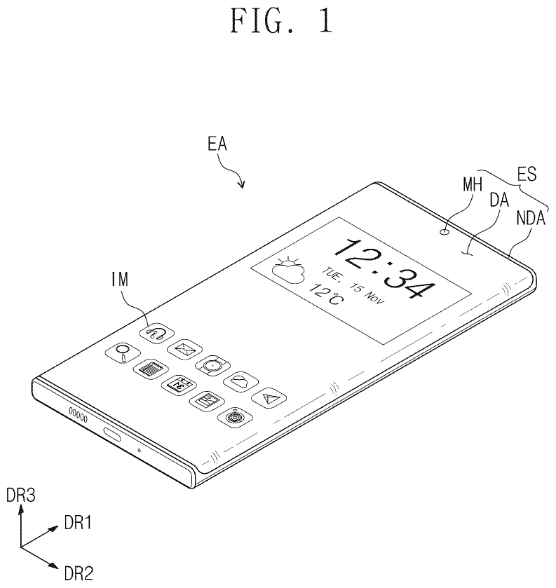

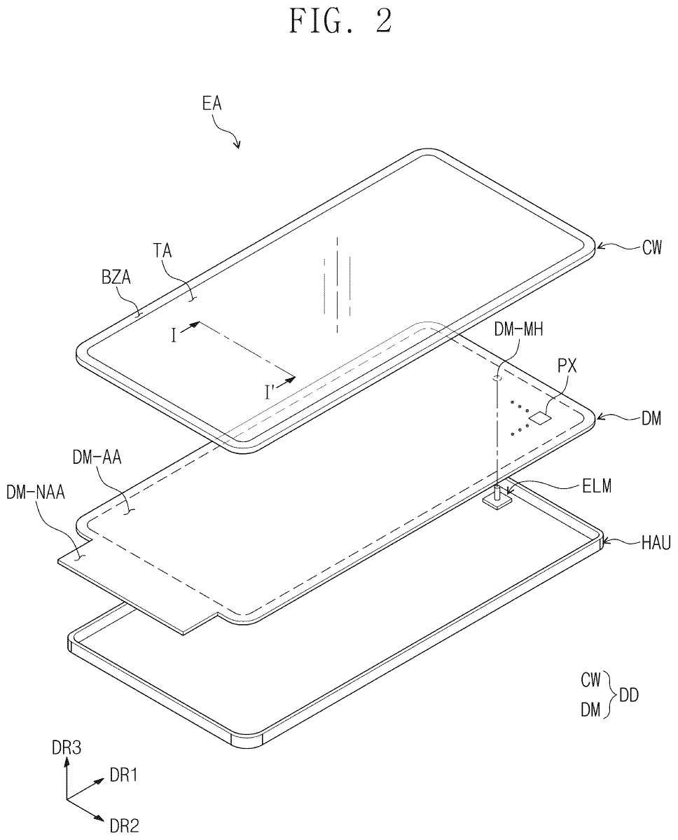

Hereinafter, a cover window according to an embodiment of the inventive concept, a display device including the cover window, and an electronic apparatus including the display device will be described with reference to the drawings. FIG. 1 is a perspective view illustrating an electronic apparatus according to an embodiment. FIG. 2 is an exploded perspective view of an electronic apparatus according to an embodiment.

An electronic apparatus EA, according to an embodiment, which is illustrated in FIG. 1 may be activated in response to an electrical signal. For example, the electronic apparatus EA may be a personal computer, a laptop computer, a personal digital terminal, a portable game console, a portable electronic device, a television, a computer monitor, an outdoor digital billboard, a car navigation unit, or a wearable device, but an embodiment of the inventive concept is not necessarily limited thereto. FIG. 1 exemplarily illustrates the electronic apparatus EA as a smartphone.

The electronic apparatus EA may include a display surface ES defined by a first direction axis DR1 and a second direction axis DR2 crossing the first direction axis DR1. The electronic apparatus EA may provide an image IM to a user through the display surface ES. The electronic apparatus EA may display the image IM, in the direction of a third direction axis DR3, on the display surface ES in each of the first direction axis DR1 and the second direction axis DR2. The image IM may be, not only a dynamic image, but also a static image.

The directions indicated by the first to third direction axes DR1, DR2, and DR3 illustrated herein are relative, and may thus be changed to other directions. Also, the directions indicated by the first to third direction axes DR1, DR2, and DR3 may be referred to as first to third directions, and may be denoted as the same reference numerals or symbols.

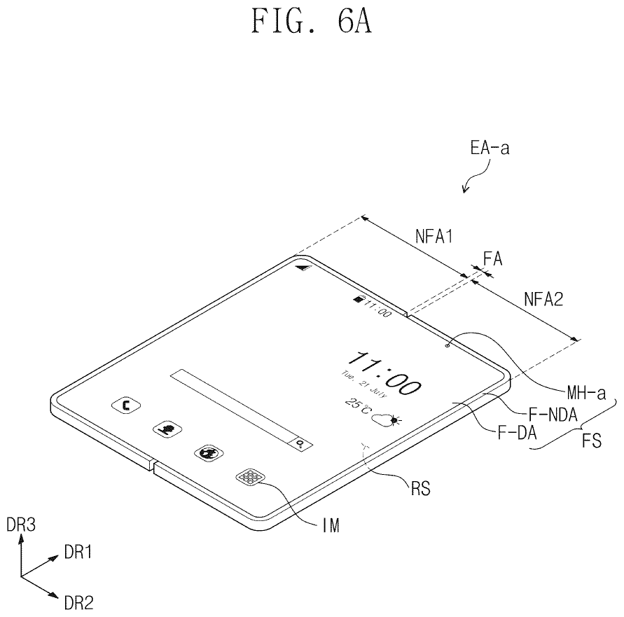

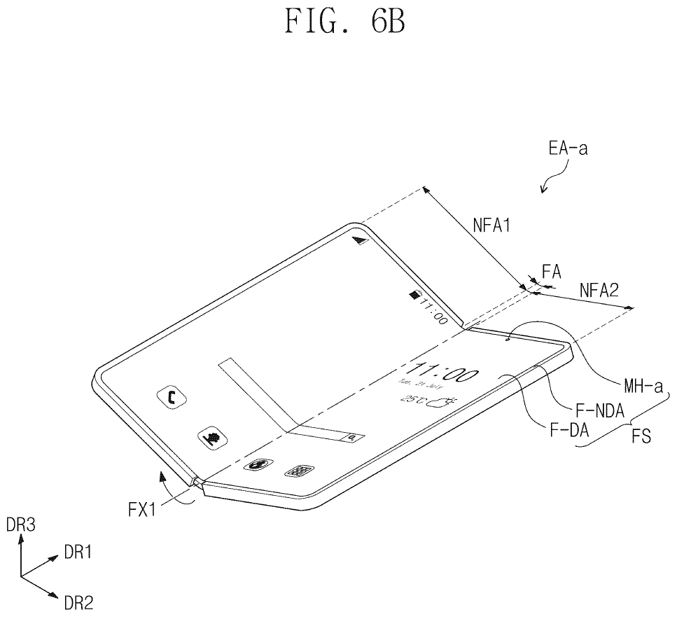

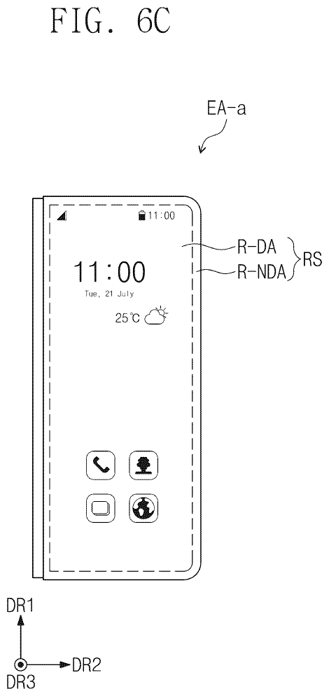

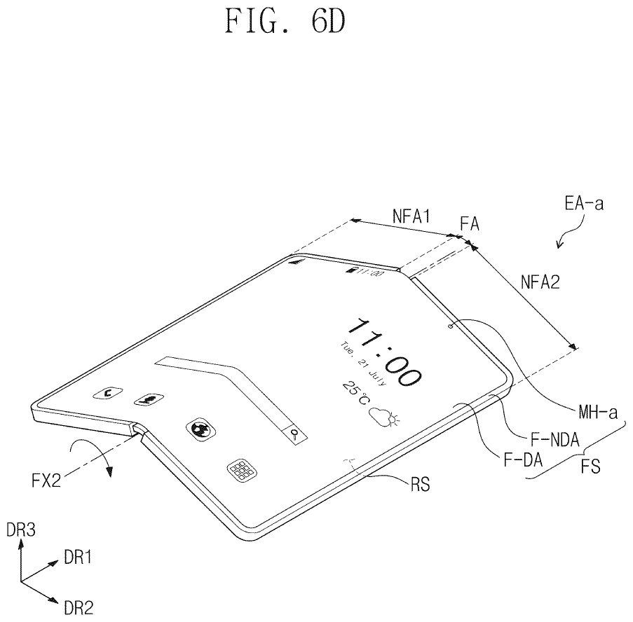

In this specification, the first direction axis DR1 is perpendicular to the second direction axis DR2, and the third direction axis DR3 may be a normal direction of the plane defined by the first direction axis DR1 and the second direction axis DR2. A thickness direction of the electronic apparatus EA may be the third direction axis DR3. The same reference numerals or symbols may be used for the thickness direction of the electronic apparatus EA and the third direction axis DR3. A front surface (or an upper surface) and a rear surface (or a lower surface) may be opposed to each other in the third direction axis DR3, and a normal direction of each of the front surface (or the upper surface) and the rear surface (or the lower surface) may be the third direction axis DR3. The front surface (or the upper surface) is referred to as a surface adjacent to the display surface ES, and the rear surface (or the lower surface) is referred to as a surface spaced apart from the display surface ES. Additionally, the rear surface (or the lower surface) is referred to as a surface adjacent to a second display surface RS (see FIG. 6A) to be described later. An upper side is referred to as a direction of getting closer to the display surface ES, and a lower side is referred to as a direction of getting farther away from the display surface ES.

In this specification, a cross section is referred to as a surface in the thickness direction DR3, and a plane is referred to as a surface perpendicular to the thickness direction DR3. A plane is referred to as a flat surface defined by the first direction axis DR1 and the second direction axis DR2.

The electronic apparatus EA may detect an external input. The external input may include various types of inputs applied from beyond the electronic apparatus EA. For example, the external input may include not only a touch by a part of a user's body such as user's hands but also an external input (for example, hovering) applied while approaching or being adjacent within a predetermined distance to the electronic apparatus EA. Additionally, the external input is not necessarily limited to a touch input and may have various forms such as force, pressure, temperature, light, etc.

The display surface ES may include a display region DA, a non-display region NDA, and a sub-region MH. The display region DA may be activated in response to an electrical signal. The display region DA may be a region in which the image IM may be displayed and various types of external inputs may be detected.

The display region DA may include a flat surface defined by the first direction axis DR1 and the second direction axis DR2. The display region DA may include a curved surface bent from at least one side of the flat surface defined by the first direction axis DR1 and the second direction axis DR2. FIG. 1 illustrates that the electronic apparatus EA, according to an embodiment, includes two curved surfaces which are respectively bent from both sides of the flat surface defined by the first direction axis DR1 and the second direction axis DR2. However, this is presented as an example, and a shape of the display region DA is not necessarily limited thereto. For example, the display region DA may include only the flat surface defined by the first direction axis DR1 and the second direction axis DR2, as well as may further include at least two curved surfaces, for example, four curved surfaces respectively bent from four side surfaces of the flat surface defined by the first direction axis DR1 and the second direction axis DR2.

The electronic apparatus EA, according to an embodiment, may be flexible. The wording “flexible” means a bendable property, and may include all of a completely foldable structure as well as a structure which is bendable to the level of several nanometers. For example, the electronic apparatus EA may be a rigid apparatus. Alternatively, the electronic apparatus EA may be a foldable apparatus.

The non-display region NDA may have a predetermined color. The non-display region NDA may be adjacent to the display region DA. The non-display region NDA may surround the display region DA. Accordingly, a shape of the display region DA may be substantially defined by the non-display region NDA. However, this is presented as an example. The non-display region NDA may be adjacent to only one side of the display region DA or may be omitted. The display region DA may have various shapes, and is not necessarily limited to any one embodiment.

The sub-region MH may detect an external subject received through the display surface ES or provide a sound signal such as voice through the display surface ES. An optical signal such as visible light or infrared light may be transmitted to the sub-region MH.

The sub-region MH may be disposed within the display region DA. However, this is illustrated as an example, and an arrangement of the sub-region MH is not necessarily limited to any one embodiment. For example, the sub-region MH might not only be surrounded by the non-display region NDA but may also be surrounded by the display region DA and the non-display region NDA. FIG. 1, etc., illustrate one sub-region MH, but the sub-region MH may also be provided in plural.

Various electronic modules ELM (see FIG. 2) may be disposed so as to correspond to the sub-region MH. For example, the electronic module ELM (see FIG. 2) may include at least one of a camera, a speaker, a light detection sensor, and a heat detection sensor. The electronic apparatus EA may include the electronic module ELM (see FIG. 2) which captures an external image by using visible light passing through the sub-region MH or determines whether an external object is approaching by using infrared light. The electronic module ELM (see FIG. 2) may also include a plurality of elements, and is not necessarily limited to any one embodiment.

Referring to FIG. 2, an electronic apparatus EA may include a display device DD and the electronic module ELM. The display device DD may include a display module DM and a cover window CW disposed on the display module DM. Additionally, the electronic apparatus EA may further include a housing HAU which accommodates the display module DM. In the display device DD, a module region DM-MH may be defined, and the electronic module ELM may be disposed so as to correspond to the module region DM-MH.

In the electronic apparatus EA illustrated in FIGS. 1 and 2, the cover window CW and the housing HAU may be coupled to constitute the exterior of the electronic apparatus EA. The housing HAU may be disposed below the display module DM. The housing HAU may include a material having a relatively high rigidity. For example, the housing HAU may include a plurality of frames and/or plates composed of glass, plastic, or metal. The housing HAU may provide a predetermined accommodation space. The display module DM may be accommodated inside the accommodation space and be protected against impact.

The display module DM may be activated in response to an electrical signal. The display module DM may be activated to display the image IM (see FIG. 1) on the display region DA (see FIG. 1) of the electronic apparatus EA. An active region DM-AA, a peripheral region DM-NAA, and the module region DM-MH may be defined in the display module DM.

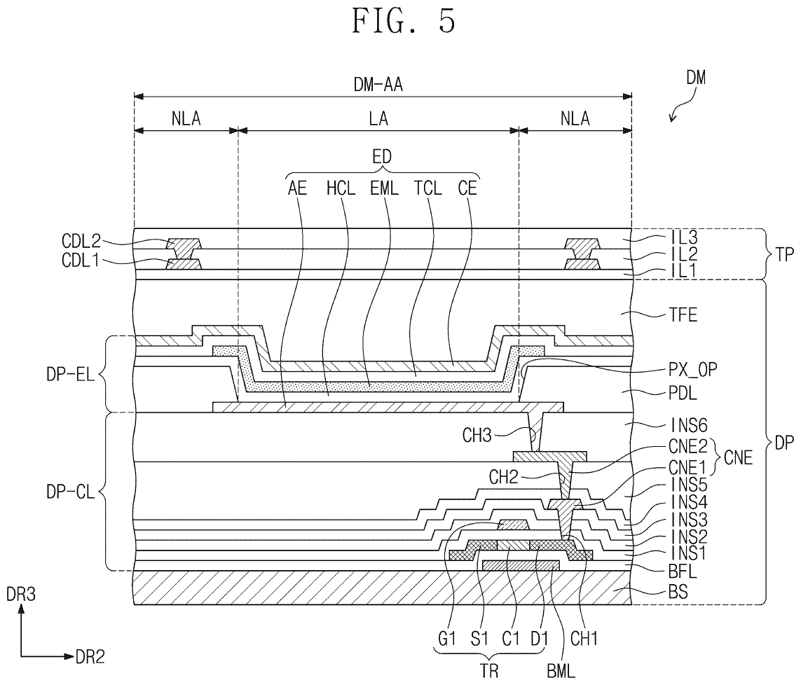

The active region DM-AA may be activated in response to an electrical signal. A pixel PX may be disposed in the active region DM-AA. The pixel PX may include a transistor TR (see FIG. 5) to be described later, and a light-emitting element ED (see FIG. 5). The peripheral region DM-NAA may be adjacent to at least one side of the active region DM-AA. A circuit, line, etc., for driving the active region DM-AA may be disposed in the peripheral region DM-NAA.

The module region DM-MH may correspond to the sub-region MH illustrated in FIG. 1. An optical signal such as visible light or infrared light may move to the module region DM-MH. The module region DM-MH may be disposed within the active region DM-AA. The module region DM-MH might not only be surrounded by the peripheral region DM-NAA but may also be surrounded by the active region DM-AA and the peripheral region DM-NAA.

The electronic module ELM may be an electronic component which outputs or receives an optical signal. The electronic module ELM may include a camera module and/or a proximity sensor. The camera module may capture an external image via the module region DM-MH.

The display device DD may further include an optical layer disposed between the display module DM and the cover window CW. The optical layer may be formed on the display module DM through a continuous process. The optical layer may include a polarization plate or a color filter layer. For example, the optical layer may include at least one of a retarder, a polarizer, a polarization film, and a polarization filter. Alternatively, the optical layer may include a plurality of color filters disposed in a predetermined arrangement. For example, the color filters may be arranged in consideration of light-emitting colors of the pixels PX. Additionally, the optical layer may further include a black matrix adjacent to the color filters.

The cover window CW may include a transmission region TA and a bezel region BZA. The transmission region TA may overlap at least a portion of the active region DM-AA of the display module DM. The transmission region TA may be an optically transparent region. The image IM (see FIG. 1) may be provided to a user through the transmission region TA.

The bezel region BZA may be a region having a lower light transmittance than the transmission region TA. The bezel region BZA may define a shape of the transmission region TA. The bezel region BZA may be adjacent to the transmission region TA and may surround the transmission region TA.

The bezel region BZA may have a predetermined color. The bezel region BZA may cover the peripheral region DM-NAA of the display module DM and block the peripheral region DM-NAA from being viewed from the outside. However, an embodiment of the inventive concept is not necessarily limited to what is illustrated in the drawings. The bezel region BZA may be disposed adjacent to only one side of the transmission region TA, and at least a portion thereof may be omitted.

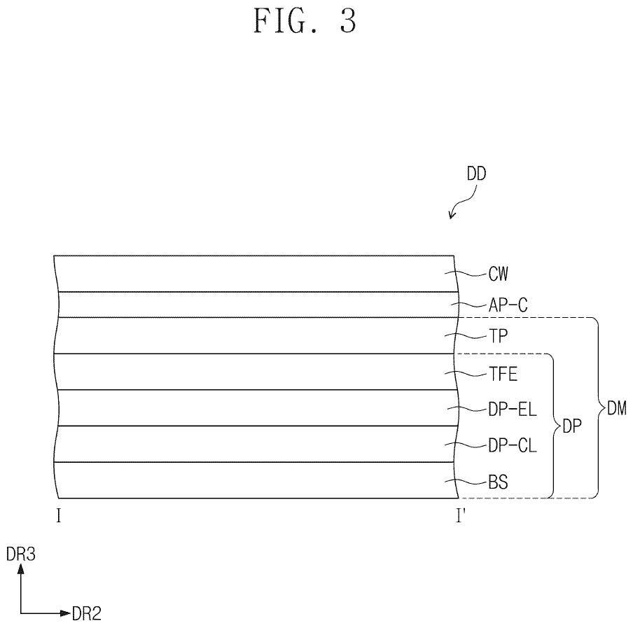

FIG. 3 is a cross-sectional view illustrating a portion taken along line I-I′ of FIG. 2. In FIG. 3, the housing HAU (see FIG. 2) is omitted for convenience of description. FIG. 3 may be a cross-sectional view illustrating components of a display device DD in detail.

Referring to FIG. 3, a display module DM may include a display panel DP and an input-sensing part TP disposed on the display panel DP. The display panel DP may be configured to substantially generate an image.

The display panel DP may include a base substrate BS, a circuit layer DP-CL, a display element layer DP-EL, and an encapsulation layer TFE, which are sequentially stacked. An additional element may also be further disposed between two adjacent layers among the base substrate BS, the circuit layer DP-CL, the display element layer DP-EL, and the encapsulation layer TFE.

The base substrate BS may provide a base surface on which the circuit layer DP-CL is disposed. The base substrate BS may be a flexible substrate which is bendable, foldable, rollable, etc. The base substrate BS may be a glass substrate, a metal substrate, a polymer substrate, etc. However, an embodiment of the inventive concept is not necessarily limited thereto, and the base substrate BS may include an inorganic layer, an organic layer, or a composite material layer.

The circuit layer DP-CL may be disposed on the base substrate BS. The circuit layer DP-CL may include an insulating layer, a semiconductor pattern, a conductive pattern, a signal line, etc. The display element layer DP-EL may be disposed on the circuit layer DP-CL. The display element layer DP-EL may include a light-emitting element ED (see FIG. 5) to be described later. For example, the light-emitting element ED (see FIG. 5) may include an organic light-emitting material, an inorganic light-emitting material, an organic-inorganic light-emitting material, quantum dots, or quantum rods. For example, the light-emitting element ED (see FIG. 5) may include a micro LED, or a nano LED.

The encapsulation layer TFE may be disposed on the display element layer DP-EL. The encapsulation layer TFE may protect the display element layer DP-EL against moisture, oxygen, and foreign substances such as dust particles. The encapsulation layer TFE may include at least one inorganic layer. For example, the encapsulation layer TFE may include an inorganic layer, an organic layer, and an inorganic layer which are sequentially stacked.

The input-sensing part TP may be disposed on the display panel DP. The input-sensing part TP may be directly disposed on the encapsulation layer TFE. Alternatively, an adhesive may also be disposed between the input-sensing part TP and the display panel DP.

In this specification, when an element is referred to as being directly disposed/provided/formed on another element, there are no intervening elements therebetween. For example, the wording, “an element is ‘directly disposed/provided/formed on’ another element” means that an element is ‘in contact with’ another element.

The input-sensing part TP may detect an external input, change the detected external input to a predetermined input signal, and provide the input signal to the display panel DP. For example, the input-sensing part TP may be a touch-sensing part which detects a touch. The input-sensing part TP may recognize a direct touch by a user, an indirect touch by a user, a direct touch by an object, an indirect touch by an object, etc.

The input-sensing part TP may detect at least one of a position or intensity (pressure) of a touch applied thereto. In an embodiment, the input-sensing part TP may have various structures or be composed of various materials, but is not necessarily limited to any one embodiment. For example, the input-sensing part TP may detect an external input in a capacitive manner. The display panel DP may receive the input signal from the input-sensing part TP and generate an image corresponding to the input signal.

The display device DD may further include an adhesive layer AP-C disposed between the display module DM and the cover window CW. The adhesive layer AP-C may bond the display module DM and the cover window CW to one another. The adhesive layer AP-C may include a pressure sensitive adhesive (PSA), an optically clear adhesive film (OCA) or an optically clear adhesive resin layer (OCR). However, this is presented as an example, and the embodiment of the inventive concept is not necessarily limited thereto. The adhesive layer AP-C may also be omitted.

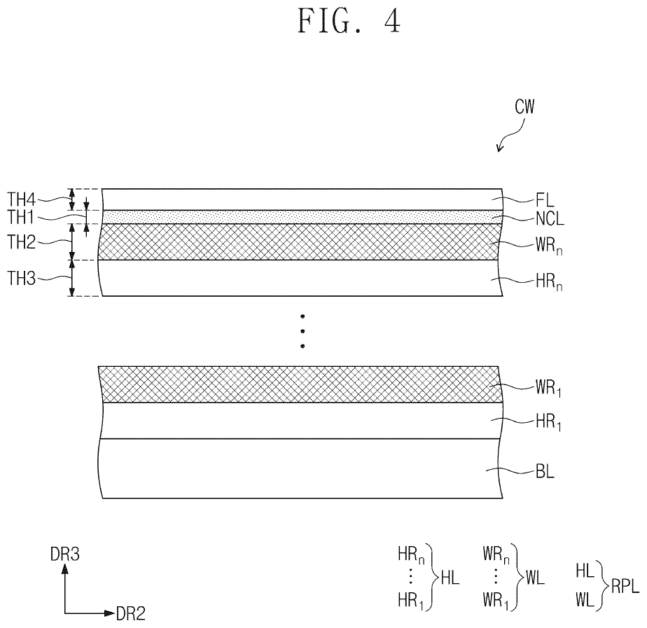

FIG. 4 is a cross-sectional view illustrating a cover window CW according to an embodiment. FIG. 4 may be a cross-sectional view illustrating, in detail, components of the cover window CW illustrated in FIG. 3.

Referring to FIG. 4, the cover window CW may include a base layer BL, an anti-reflection layer RPL disposed on the base layer BL, and a nitrogen-containing layer NCL disposed on the anti-reflection layer RPL. Additionally, the cover window CW may further include a functional layer FL disposed on the nitrogen-containing layer NCL. The functional layer FL may be spaced apart from the anti-reflection layer RPL with the nitrogen-containing layer NCL disposed therebetween.

The base layer BL may provide a base surface on which the anti-reflection layer RPL is disposed. The base layer BL may include glass or a polymer film. For example, the base layer BL may be a flexible polymer film. The base layer BL may include at least one of polyethylene terephthalate, polyimide, polyacrylate, polymethylmethacrylate, polycarbonate, polyethylenenaphthalate, polyvinylidene chloride, polyvinylidene difluoride, polystyrene, and an ethylene vinylalcohol copolymer. However, this is presented as an example, and a material of the base layer BL is not necessarily limited thereto.

The anti-reflection layer RPL may include a high-refractive-index layer HL and a low-refractive-index layer WL disposed on the high-refractive-index layer HL. The high-refractive-index layer HL may be provided as a plurality of high-refractive-index layers HR₁ to HRₙ. The low-refractive-index layer WL may be provided as a plurality of low-refractive-index layers WR₁ to WRₙ. Here, n is an integer of 2 or more. The thicknesses of the plurality of high-refractive-index layers HR₁ to HRₙ may be different from each other. The thicknesses of the plurality of low-refractive-index layers WR₁ to WRₙ may be different from each other.

The anti-reflection layer RPL including the plurality of high-refractive-index layers HR₁ to HRₙ and the plurality of low-refractive-index layers WR₁ to WRₙ may reduce reflectance through destructive interference caused by the difference in the refractive indices. Accordingly, the cover window CW including the anti-reflection layer RPL exhibits low reflectance, and may thus improve display quality of a display device DD. The plurality of high-refractive-index layers HR₁ to HRₙ and the plurality of low-refractive-index layers WR₁ to WRₙ may be alternately disposed. The nitrogen-containing layer NCL may be disposed on the n-th low-refractive-index layer WRₙ. For example, the high-refractive-index layer HL and the low-refractive-index layer WL may each be provided as two, three, or five layers.

A refractive index of the high-refractive-index layer HL may be within a range of about 1.7 to about 2.5, inclusive. The high-refractive-index layer HL may include a nitride containing silicon (Si). For example, the high-refractive-index layer HL may include at least one of silicon nitride (SiNₓ), silicon aluminum nitride (SiAlN), aluminum nitride (AlN), germanium dioxide (GeO₂), zirconium dioxide (ZrO₂), and titanium dioxide (TiO₂). However, this is presented as an example, and the high-refractive-index layer HL may include any material having a high refractive index known in the art without limitation.

A refractive index of the low-refractive-index layer WL may be within a range of about 1.3 to about 1.6, inclusive. The low-refractive-index layer WL may include an oxide including silicon (Si) and/or an oxide including aluminum (Al). For example, the low-refractive-index layer WL may include at least one of silicon oxide (SiOₓ), aluminum oxide (Al₂O₃), and silicon oxynitride (SiON). The low-refractive-index layer WL may include silicon dioxide (SiO₂). However, this is presented as an example, and the low-refractive-index layer WL may further include a material having a low refractive index known in the art.

The nitrogen-containing layer NCL may be disposed on the low-refractive-index layer WL. The nitrogen-containing layer NCL may be directly disposed on the n-th low-refractive-index layer WRₙ disposed on the uppermost part of the anti-reflection layer RPL. The nitrogen-containing layer NCL may be a layer formed by directly providing nitrogen gas on a surface of the n-th low-refractive-index layer WRₙ. The nitrogen-containing layer NCL may be formed by performing a nitrogen gas treatment on the surface of the n-th low-refractive-index layer WRₙ. Nitrogen of the nitrogen-containing layer NCL may be chemically bonded to a material of the n-th low-refractive-index layer WRₙ. The n-th low-refractive-index layer WRₙ may include a material which forms a chemical bond with nitrogen. The nitrogen-containing layer NCL may be formed by providing nitrogen in a plasma state to the surface of the n-th low-refractive-index layer WRₙ through a resputtering process. The nitrogen-containing layer NCL may include a material formed by chemically bonding nitrogen to the material of the n-th low-refractive-index layer WRₙ. For example, the nitrogen-containing layer NCL may include silicon nitride and/or silicon oxynitride. The silicon nitride and silicon oxynitride may be materials formed by chemically bonding nitrogen to the material of the low-refractive-index layer WRₙ. The silicon nitride and silicon oxynitride are materials which exhibit high hardness according to a microstructure, and a member (for example, the nitrogen-containing layer NCL) including the silicon nitride and silicon oxynitride may have the maximum hardness of about 24 GPa. Accordingly, the nitrogen-containing layer NCL formed on the n-th low-refractive-index layer WRₙ may increase hardness of the anti-reflection layer RPL while maintaining excellent reflectance.

As reflectance of the low-refractive-index layer decreases, reflectance of the anti-reflection layer improves, but hardness and scratch resistance decrease. Materials, having a low refractive index, which are included in the low-refractive-index layer, generally exhibit low hardness. The cover window, according to an embodiment, includes the nitrogen-containing layer NCL formed by performing a nitrogen gas treatment on the surface of the low-refractive-index layer WL, and may thus exhibit excellent hardness and scratch resistance while maintaining excellent reflectance.

In an embodiment, the nitrogen-containing layer NCL may have a thickness TH1 within a range of about 0.5 nm to about 5 nm, inclusive. The refractive index of the nitrogen-containing layer NCL may be greater than the refractive index of the low-refractive-index layer WL. The refractive index of the nitrogen-containing layer NCL may be greater than the refractive index of the most adjacent n-th low-refractive-index layer WRₙ. The refractive index of the nitrogen-containing layer NCL may be less than the refractive index of the high-refractive-index layer HL. The thickness TH1 of the nitrogen-containing layer NCL may be less than the thickness TH2 of the n-th low-refractive-index layer WRₙ and the thickness TH3 of the n-th high-refractive-index layer HRₙ. The thickness TH1 of the nitrogen-containing layer NCL may be less than the thickness of each of the plurality of low-refractive-index layers WR₁ to WRₙ. The thickness TH1 of the nitrogen-containing layer NCL may be less than the thickness of each of the plurality of high-refractive-index layers HR₁ to HRₙ. The thickness TH1 of the nitrogen-containing layer NCL may be less than the thickness TH4 of the functional layer FL. Since the nitrogen-containing layer NCL has a relatively high refractive index, the nitrogen-containing layer NCL may be formed to have a thin thickness TH1 within a range of about 0.5 nm to about 5 nm, inclusive, such that reflectance is not increased. When the layer disposed on the uppermost part of the anti-reflection layer RPL has a relatively high refractive index and relatively large thickness, reflectance increases.

The nitrogen-containing layer having a thickness of less than about 0.5 nm may be considered extremely small, so that hardness and scratch resistance of the anti-reflection layer are not improved. The nitrogen-containing layer having a thickness of greater than about 5 nm increases reflectance of the anti-reflection layer. Additionally, the nitrogen-containing layer having a thickness of greater than about 5 nm is formed not by treating a surface of the low-refractive-index layer, but by performing a deposition process. The refractive index of the nitrogen-containing layer is greater than the refractive index of the most adjacent n-th low-refractive-index layer, and the nitrogen-containing layer having a great thickness (for example, a thickness of greater than about 5 nm) increases reflectance. The nitrogen-containing layer NCL, according to an embodiment, has a thickness TH1 within a range of about 0.5 nm to about 5 nm, inclusive, and may thus improve hardness and scratch resistance while maintaining excellent reflectance. In an embodiment, the cover window CW including the nitrogen-containing layer NCL may achieve improved hardness and scratch resistance while exhibiting excellent reflectance. The cover window CW, according to an embodiment, may exhibit excellent reliability.

The functional layer FL may include a polymer film. The functional layer FL may include at least one of an antistatic agent, a hard coating agent, and an anti-fingerprint agent. For example, the functional layer FL may include perfluoropolyether (PFPE). The functional layer FL may also be omitted.

The cover window CW may further include an auxiliary layer between the base layer BL and the anti-reflection layer RPL. The auxiliary layer may increase bonding strength between the base layer BL and the anti-reflection layer RPL and enhance mechanical properties (for example, wear resistance) of the cover window CW. For example, the auxiliary layer may include silicon oxide.

Table 1 below shows evaluation results of a cover window according to Comparative Example and Example. The cover window is evaluated by using a spectrophotometer CM-3700A (a product of Konica Minolta, Inc.).

In Table 1, Comparative Example 1, Example 1, and Example 2 differ from each other in whether the nitrogen-containing layer is formed. In Comparative Example 1, a nitrogen-containing layer is not formed in the cover window, and in Examples 1 and 2, the nitrogen-containing layer is formed in the cover window. The cover window of Comparative Example 1 includes a base layer, an auxiliary layer, an anti-reflection layer, and an anti-fingerprint layer, which are sequentially stacked, and does not include the nitrogen-containing layer. The cover window of each of Examples 1 and 2 includes the base layer, the auxiliary layer, the anti-reflection layer, the nitrogen-containing layer, and the anti-fingerprint layer, which are sequentially stacked. The cover window of each of Examples 1 and 2 is the cover window according to an embodiment.

The cover window of each of Examples 1 and 2 includes the nitrogen-containing layer formed by providing nitrogen to a surface of a sixth layer having a thickness of about 91 nm though a resputtering process, and the sixth layer is the low-refractive-index layer including a material having a low refractive index. The cover window of Example 1 is provided with nitrogen for about 1 minute, and the cover window of Example 2 is provided with nitrogen for about 2 minutes. In this case, the nitrogen-containing layer is formed as an extremely small layer, and has a thickness within a range of about 1 nm to about 3 nm, inclusive. A thickness of the nitrogen-containing layer formed as an extremely small layer may be confirmed with values within a certain range.

In the cover window of each of Comparative Example 1, Example 1, and Example 2, the auxiliary layer has a thickness of about 47 nm and includes silicon oxide. In the cover window of each of Comparative Example 1, Example 1, and Example 2, the anti-fingerprint layer has a thickness of about 10 nm.

In the cover window of each of Comparative Example 1, Example 1, and Example 2, the anti-reflection layer includes first to sixth layers which are sequentially stacked, and thicknesses of the first to sixth layers are about 21 nm, about 43 nm, about 56 nm, about 21 nm, about 161 nm, and about 91 nm, respectively. The first, third, and fifth layers are the high-refractive-index layers including silicon nitride (SiNₓ). The second, fourth, and sixth layers are the low-refractive-index layers including silicon oxide (SiOₓ).

In Table 1, a* and b* indicate color coordinates, and represent cross-sectional color coordinates. ΔE*ab represents a value calculated by the following Equation.

$$Δ {E}^{*} ab = {[ {( Δ {L}^{*} )}^{2} + {( Δ {a}^{*} )}^{2} + {( Δ {b}^{*} )}^{2} ]}^{1 / 2} \qquad Equation ( 1 )$$

In Table 1, the term ‘initial’ represents a value obtained before performing a vibration wear test, and the term ‘later’ represents a value obtained after performing the vibration wear test. In Table 1, R represents a reflectance value, and ΔSCE represents the amount of change in specular component excluded (SCE) reflectance, for example, a difference value between the SCE reflectance before and after performing the vibration wear test. The vibration wear test was conducted to confirm an improvement level of scratch resistance.

TABLE 1

| | | Comparative | | |
|---|---|---|---|---|
| | | Example 1 | Example 1 | Example 2 |
| Anti-fingerprint | Thickness | 10 | | |
| layer | (nm) | | | |
| Sixth layer | | 91 | | |
| Fifth layer | | 161 | | |
| Fourth layer | | 21 | | |
| Third layer | | 56 | | |
| Second layer | | 43 | | |
| First layer | | 21 | | |
| Auxiliary layer | | 47 | | |
| Initial | R (%) | 0.86 | 0.85 | 0.83 |
| | a* | −5.63 | −4.21 | −4.12 |
| | b* | −0.69 | −1.11 | −1.83 |
| | SCE (%) | 0.012 | 0.010 | 0.012 |
| Later | R (%) | 1.11 | 1.06 | 0.98 |
| | a* | −4.09 | −4.04 | −3.91 |
| | b* | −2.54 | −1.26 | −1.61 |
| | SCE (%) | 0.152 | 0.130 | 0.117 |

| | | | |
|---|---|---|---|
| ΔE*ab | 3.18 | 1.97 | 1.09 |
| ΔSCE (%) | 0.140 | 0.120 | 0.105 |

Referring to Table 1, it may be seen that ΔE*ab and ASCE of the cover windows of Examples 1 and 2 show values less than that of the cover window of Comparative Example 1. ΔE*ab indicates a value related to reflectance change and color change in a worn region, and means that the larger a value is, the higher the levels of reflectance change and color change are. ASCE indicates a value related to surface roughness, and means that the larger a value is, the higher the levels of surface roughness and surface damage are. Therefore, it may be seen that the cover windows of Examples 1 and 2 have low levels of reflectance change, color change, and surface damage. As described above, in Comparative Example 1, the nitrogen-containing layer is not formed in the cover window. The cover window of each of Examples 1 and 2 includes the nitrogen-containing layer formed by providing nitrogen to the sixth layer, which is the uppermost part of the low-refractive-index layer, and is the cover window according to an embodiment. Accordingly, it may be seen that the cover window including the nitrogen-containing layer according to an embodiment may exhibit improved scratch resistance while maintaining excellent reflectance.

Table 2 below shows evaluation results of a cover window according to Experimental Example. The cover window is evaluated by using a spectrophotometer CM-3700A (a product of Konica Minolta, Inc.).

The cover windows of Experimental Examples 1 to 4 are formed by depositing a layer including silicon oxynitride (SiON) on the sixth layer which is the low-refractive-index layer, and have a difference in a thickness and/or a refractive index of the layer including silicon oxynitride. Hereinafter, for convenience of description, the layer containing silicon oxynitride is referred to as a “deposition layer”.

In the cover window of Experimental Example 1, the deposition layer has a thickness of about 5 nm and a refractive index of about 1.60. In the cover window of Experimental Example 2, the deposition layer has a thickness of about 10 nm and a refractive index of about 1.60. In the cover window of Experimental Example 3, the deposition layer has a thickness of about 5 nm and a refractive index of about 1.71. In the cover window of Experimental Example 4, the deposition layer has a thickness of about 10 nm, and a refractive index of about 1.71. In the cover window of each of Experimental Examples 1 to 4, the refractive index of the deposition layer is a refractive index of light having a wavelength of about 550 nm.

The cover window of Experimental Example 1 and the cover window of Experimental Example 2 include deposition layers which have different thicknesses and the same refractive index. The cover window of Experimental Example 3 and the cover window of Experimental Example 4 include deposition layers which have different thicknesses and the same refractive index. The cover window of Experimental Example 1 and the cover window of Experimental Example 3 include deposition layers which have the same thickness and different refractive indices. The cover window of Experimental Example 2 and the cover window of Experimental Example 4 include deposition layers which have the same thickness and different refractive indices.

The cover window of each of Experimental Examples 1 to 4 includes a base layer, an auxiliary layer, an anti-reflection layer, and a deposition layer, which are sequentially stacked. In the cover window of each of Experimental Examples 1 to 4, the auxiliary layer includes silicon dioxide (SiO₂) and has a thickness of about 47 nm.

In the cover window of each of Experimental Examples 1 to 4, the anti-reflection layer includes first to sixth layers which are sequentially stacked, and thicknesses of the first to sixth layers are about 21 nm, about 43 nm, about 56 nm, about 21 nm, about 161 nm, and about 86 nm, respectively. The first, third, and fifth layers are high-refractive-index layers including Si₃N₄. The second, fourth, and sixth layers are low-refractive-index layers including SiO₂.

In Table 2, R indicates a reflectance value, and a* and b* represent color coordinates.

TABLE 2

| | | Experi- | Experi- | Experi- | Experi- |
|---|---|---|---|---|---|
| | | mental | mental | mental | mental |
| | | Example 1 | Example 2 | Example 3 | Example 4 |
| Deposition | Thickness | 5 | 10 | 5 | 10 |
| layer | (nm) | | | | |
| Sixth layer | | 86 | 81 | 86 | 81 |
| Fifth layer | | 161 | 161 | 161 | 161 |
| Fourth layer | | 21 | 21 | 21 | 21 |
| Third layer | | 56 | 56 | 56 | 56 |
| Second layer | | 43 | 43 | 43 | 43 |
| First layer | | 21 | 21 | 21 | 21 |
| Auxiliary | | 47 | 47 | 47 | 47 |
| layer | | | | | |

| | | | | |
|---|---|---|---|---|
| R (%) | 0.94 | 1.06 | 1.08 | 1.41 |
| a* | −6.20 | −6.22 | −6.00 | −5.58 |
| b* | −1.14 | −1.32 | −1.57 | −2.21 |

Referring to Table 2, it may be seen that the reflectance of the cover window of Experimental Example 2 increases compared to that of the cover window of Experimental Example 1. As described above, the cover window of Experimental Example 1 and the cover window of Experimental Example 2 differ from each other in a thickness of the deposition layer. It may be seen that the reflectance increases in Experimental Example 2 the deposition layer of which has a greater thickness. It may be seen that the reflectance of the cover window of Experimental Example 4 increases compared to that of the cover window of Experimental Example 3. As described above, the cover window of Experimental Example 3 and the cover window of Experimental Example 4 differ from each other in a thickness of the deposition layer. It may be seen that the reflectance increases in Experimental Example 4 the deposition layer of which has a greater thickness. Accordingly, it may be seen that when a layer having a high refractive index and a great thickness is deposited on the uppermost part of the low-refractive-index layer of the anti-reflection layer, the reflectance increases. The nitrogen-containing layer, according to an embodiment, has a thickness within a range of about 0.5 nm to about 5 nm, inclusive, and is formed by resputtering nitrogen gas to the uppermost surface of the low-refractive-index layer of the anti-reflection layer. Therefore, it may be seen that the nitrogen-containing layer may exhibit improved scratch resistance while maintaining excellent reflectance.

FIG. 5 is a cross-sectional view illustrating, in detail, a display module DM illustrated in FIG. 3. FIG. 5 may be a cross-sectional view illustrating, in detail, an active region DM-AA of the display module DM.

Referring to FIG. 5, a base substrate BS may include a single layer or a plurality of layers. For example, the base substrate BS may include a first synthetic resin layer, a multi- or single-layered inorganic layer, or a second synthetic resin layer disposed on the multi- or single-layered inorganic layer. The first synthetic resin layer and the second synthetic resin layer may each include a polyimide-based resin. Additionally, the first synthetic resin layer and the second synthetic resin layer may each include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, a “˜˜” based resin is considered as including a functional group of “˜˜”.

A display panel DP may include a transistor TR and a light-emitting element ED. The transistor TR and the light-emitting element ED may be disposed on the base substrate BS. FIG. 5 illustrates one transistor TR, but the display panel DP may substantially include at least one capacitor and a plurality of transistors for driving the light-emitting element ED.

A circuit layer DP-CL may include an insulating layer, a semiconductor pattern, a conductive pattern, a signal line, etc. For example, the circuit layer DP-CL may include a switching transistor or a driving transistor for driving the light-emitting element ED of a display element layer DP-EL.

The circuit layer DP-CL may include a shielding electrode BML, the transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stacked structure of the circuit layer DP-CL illustrated in FIG. 5 is presented as an example, and a stacked structure of the circuit layer DP-CL may be changed according to a configuration of the display panel DP and processes for the circuit layer DP-CL, etc.

The shielding electrode BML may be disposed on the base substrate BS. The shielding electrode BML may overlap the transistor TR. The shielding electrode BML may block light incident onto the transistor TR from below the display panel DP to protect the transistor TR. The shielding electrode BML may include an electrically conductive material. When a voltage is applied to the shielding electrode BML, a threshold voltage of the transistor TR disposed on the shielding electrode BML may be maintained. However, an embodiment of the inventive concept is not necessarily limited thereto, and the shielding electrode BML may be a floating electrode. The shielding electrode BML may also be omitted.

The buffer layer BFL may be disposed on the base substrate BS and cover the shielding electrode BML. The buffer layer BFL may include an inorganic layer. The buffer layer BFL may increase a bonding force between the base substrate BS and a semiconductor pattern or a conductive pattern, which is disposed on the buffer layer BFL.

The transistor TR may include a source S1, a channel C1, a drain D1, and a gate G1. The source S1, the channel C1, and the drain D1 of the transistor TR may be formed from a semiconductor pattern. The semiconductor pattern of the transistor TR may include polysilicon, amorphous silicon, or a metal oxide. However, any material having semiconductor properties may be applied without limitation, and is not necessarily limited to any one embodiment.

The semiconductor pattern may include a plurality of regions divided according to a conductivity level. In the semiconductor pattern, a region, which is doped with a dopant or in which a metal oxide is reduced, may have a high conductivity, and may serve substantially as a source electrode and a drain electrode of the transistor TR. A highly conductive region of the semiconductor pattern may correspond to the source S1 and the drain D1 of the transistor TR. In the semiconductor pattern, a region, which is undoped or lightly doped or which has a low conductivity due to a non-reduced metal oxide, may correspond to the channel C1 (or active) of the transistor TR.

The first insulating layer INS1 may cover the semiconductor pattern of the transistor TR and be disposed on the buffer layer BFL. The gate G1 of the transistor TR may be disposed on the first insulating layer INS1. In a plan view, the gate G1 may overlap the channel C1 of the transistor TR. The gate G1 may function as a mask during the process of doping the semiconductor pattern of the transistor TR.

The second insulating layer INS2 may cover the gate G1 and be disposed on the first insulating layer INS1. The third insulating layer INS3 may be disposed on the second insulating layer INS2.

The connection electrode CNE may include a first connection electrode CNE1 and a second connection electrode CNE2 which electrically connect the transistor TR and the light-emitting element ED. However, a configuration of the connection electrode CNE which electrically connects the transistor TR to the light-emitting element ED is not necessarily limited to the configuration described above. Either of the first connection electrode CNE1 or the second connection electrode CNE2 may be omitted, or an additional connection electrode may be further included.

The first connection electrode CNE1 may be disposed on the third insulating layer INS3. The first connection electrode CNE1 may be connected to the drain D1 via a first contact hole CH1 passing through the first to third insulating layers INS1 to INS3. The fourth insulating layer INS4 may cover the first connection electrode CNE1 and be disposed on the third insulating layer INS3. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 via a second contact hole CH2 passing through the fourth and fifth insulating layers INS4 and INS5. The sixth insulating layer INS6 may cover the second connection electrode CNE2 and be disposed on the fifth insulating layer INS5.

The first to sixth insulating layers INS1 to INS6 may each include an inorganic layer or an organic layer. For example, the inorganic layer may include at least one of aluminum oxide, titanium oxide, silicon oxide, silicon oxynitride, zirconium oxide, and hafnium oxide. The organic layer may also include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin.

The display element layer DP-EL may include a pixel-defining film PDL and the light-emitting element ED. The light-emitting element ED may include a first electrode AE, a second electrode CE disposed on the first electrode AE, and a light-emitting layer EML disposed between the first electrode AE and the second electrode CE. Additionally, the light-emitting element ED may further include a hole control layer HCL and an electron control layer TCL. The hole control layer HCL may be disposed between the first electrode AE and the light-emitting layer EML. The electron control layer TCL may be disposed between the light-emitting layer EML and the second electrode CE.

The light-emitting element ED may emit light. For example, the light-emitting element ED may include an organic light-emitting material, an inorganic light-emitting material, an organic-inorganic light-emitting material, quantum dots, or quantum rods. For example, the light-emitting element ED may include a micro LED, or a nano LED.

The first electrode AE may be disposed on the sixth insulating layer INS6. The first electrode AE may be connected to the second connection electrode CNE2 via a third contact hole CH3 passing through the sixth insulating layer INS6. The first electrode AE may be electrically connected to the drain D1 of the transistor TR via the first and second connection electrodes CNE1 and CNE2.

The first electrode AE may be formed of a metal, metal alloy, or an electrically conductive compound. The first electrode AE may be an anode or a cathode. However, an embodiment of the inventive concept is not necessarily limited thereto. Also, the first electrode AE may be a pixel electrode. The first electrode AE may be a transmissive electrode, a transflective electrode, or a reflective electrode. The first electrode AE may include: at least one selected from among Ag, Mg, Cu, Al, Pt, Pd, Au, Ni, Nd, Ir, Cr, Li, Ca, LiF, Mo, Ti, W, In, Sn, and Zn; a compound of two or more materials selected from thereamong; a mixture of two or more materials selected from thereamong; or oxides thereof.

When the first electrode AE is the transmissive electrode, the first electrode AE may include a transparent metal oxide, for example, indium tin oxide (ITO), indium zinc oxide (IZO), zinc oxide (ZnO), indium tin zinc oxide (ITZO), etc. When the first electrode AE is the transflective electrode or the reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (for example, a mixture of Ag and Mg). Alternatively, the first electrode AE may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), etc. For example, the first electrode AE may have a three-layered structure of ITO/Ag/ITO, but is not necessarily limited thereto. Also, an embodiment of the inventive concept is not necessarily limited thereto, and the first electrode AE may include the above-described metal materials, a combination of two or more metal materials selected from thereamong, oxides of the above-described metal materials, etc.

The pixel-defining film PDL may be disposed on the sixth insulating layer INS6. A light-emitting opening PX_OP which exposes a portion of the first electrode AE may be defined in the pixel-defining film PDL. A portion, of the first electrode AE, which is exposed by the light-emitting opening PX_OP may be defined as a light-emitting region LA.

An active region DM-AA of the display module DM may include the light-emitting region LA and a light-blocking region NLA. A region, in which the pixel-defining film PDL is disposed, may correspond to the light-blocking region NLA. The light-blocking region NLA may surround the light-emitting region LA in the active region DM-AA.

The hole control layer HCL may be disposed on the first electrode AE and the pixel-defining film PDL. The hole control layer HCL may be provided as a common layer overlapping the light-emitting region LA and the light-blocking region NLA. The hole control layer HCL may also be disposed in a region corresponding to the light-emitting opening PX_OP. The hole control layer HCL may include at least one of a hole transport layer, a hole injection layer, and an electron blocking layer. The hole control layer HCL may include a typical hole injection material and/or a typical hole transport material.

The light-emitting layer EML may be disposed on the hole control layer HCL. The light-emitting layer EML may be disposed in a region corresponding to the light-emitting opening PX_OP. Alternatively, the light-emitting layer EML may also be provided as a common layer. The light-emitting layer EML may include an organic light-emitting material and/or an inorganic light-emitting material. The light-emitting layer EML may emit light having one color of red, green, or blue. For example, the light-emitting layer EML may emit blue color light.

The electron control layer TCL may be disposed on the light-emitting layer EML. The electron control layer TCL may be provided as a common layer overlapping the light-emitting region LA and the light-blocking region NLA. The electron control layer TCL may also be disposed in a region corresponding to the light-emitting opening PX_OP. The electron control layer TCL may include at least one of an electron transport layer, an electron injection layer, and a hole blocking layer. The electron control layer TCL may include a typical electron injection material and/or a typical electron transport material.

The second electrode CE may be disposed on the electron control layer TCL. The second electrode CE may be provided as a common layer overlapping the light-emitting region LA and the light-blocking region NLA. The second electrode CE may be a common electrode. The second electrode CE may be a cathode or an anode, but an embodiment of the inventive concept is not necessarily limited thereto. For example, when the first electrode AE is an anode, the second electrode CE may be a cathode, and when the first electrode AE is a cathode, the second electrode CE may be an anode.

The second electrode CE may be a transmissive electrode, a transflective electrode, or a reflective electrode. When the second electrode CE is the transmissive electrode, the second electrode CE may include a transparent metal oxide, for example, indium tin oxide (ITO), indium zinc oxide (IZO), zinc oxide (ZnO), indium tin zinc oxide (ITZO), etc.

When the second electrode CE is the transflective electrode or the reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (for example, AgMg, AgYb, or MgYb). Alternatively, the second electrode CE may have a multi-layered structure including a reflective film or a transflective film, which is formed of the above-described materials, and a transparent conductive film formed of indium tin oxide (ITO), indium zinc oxide (IZO), zinc oxide (ZnO), indium tin zinc oxide (ITZO), etc. For example, the second electrode CE may include the above-described metal materials, a combination of two or more metal materials selected from thereamong, oxides of the above-described metal materials, etc.

An encapsulation layer TFE may be disposed on the display element layer DP-EL. The encapsulation layer TFE may be disposed on the second electrode CE and cover the light-emitting element ED. The encapsulation layer TFE may protect the display element layer DP-EL against moisture, oxygen, and/or foreign substances such as dust particles. The encapsulation layer TFE may include a plurality of thin films.

The encapsulation layer TFE may include at least one inorganic film. For example, the encapsulation layer TFE may include inorganic films, disposed on the second electrode CE, and an organic film disposed between the inorganic films. The inorganic film may protect the light-emitting element ED against moisture/oxygen, and the organic film may protect the light-emitting element ED against foreign substances such as dust particles.

An input-sensing part TP may be disposed on the display panel DP. For example, the input-sensing part TP may be directly disposed on the encapsulation layer TFE of the display panel DP. Alternatively, an adhesive layer may also be disposed between the input-sensing part TP and the display panel DP.

The input-sensing part TP may include a first sensing-insulating layer IL1, a second sensing-insulating layer IL2, and a third sensing-insulating layer IL3. The input-sensing part TP may include at least one conductive layer disposed on the sensing-insulating layers. The input-sensing part TP may include a first conductive layer CDL1 and a second conductive layer CDL2.

The first sensing-insulating layer IL1 may be disposed on the encapsulation layer TFE. The first sensing-insulating layer IL1 may include at least one inorganic insulating layer. The first sensing-insulating layer IL1 may be in contact with the encapsulation layer TFE. Alternatively, the first sensing-insulating layer IL1 may also be omitted, and in this case, the first conductive layer CDL1 may be in contact with the encapsulation layer TFE.

The first conductive layer CDL1 may be disposed on the first sensing-insulating layer IL1. The first conductive layer CDL1 may include a plurality of first conductive patterns. The plurality of first conductive patterns may be disposed on the first sensing-insulating layer IL1. The second sensing-insulating layer IL2 may be disposed on the first sensing-insulating layer IL1 so as to cover at least a portion of the first conductive layer CDL1.

The second conductive layer CDL2 may be disposed on the second sensing-insulating layer IL2. The second conductive layer CDL2 may include a plurality of second conductive patterns. The plurality of second conductive patterns may be disposed on the second sensing-insulating layer IL2. The plurality of second conductive patterns may be respectively connected to the plurality of first conductive patterns via a contact hole formed in the second sensing-insulating layer IL2.

The plurality of first conductive patterns of the first conductive layer CDL1 and the plurality of second conductive patterns of the second conductive layer CDL2 may each be disposed to correspond to the light-blocking region NLA. The plurality of first conductive patterns of the first conductive layer CDL1 and the plurality of second conductive patterns of the second conductive layer CDL2 may each be a mesh pattern.

The third sensing-insulating layer IL3 may be disposed on the second sensing-insulating layer IL2 and cover the second conductive layer CDL2. The second sensing-insulating layer IL2 and the third sensing-insulating layer IL3 may each include an inorganic insulating layer or an organic insulating layer.

The first conductive layer CDL1 and the second conductive layer CDL2 may each have a single-layered structure or a multi-layered structure in which layers are stacked along the third direction DR3. The conductive layers CDL1 and CDL2 having a single-layered structure may each include a metal layer or a transparent conductive layer. The metal layer may include molybdenum, silver, titanium, copper, aluminum, or an alloy thereof. The transparent conductive layer may include transparent conductive oxides such as an indium tin oxide (ITO), an indium zinc oxide (IZO), a zinc oxide (ZnO), and an indium tin zinc oxide (ITZO). Also, the transparent conductive layer may include a conductive polymer such as PEDOT, a metal nanowire, graphene, etc.

The conductive layers CDL1 and CDL2 having a multi-layered structure may include metal layers. For example, the metal layers may have a three-layered structure of titanium (Ti)/aluminum (Al)/titanium (Ti). The conductive layers CDL1 and CDL2 having a multi-layered structure may include at least one metal layer and at least one transparent conductive layer.

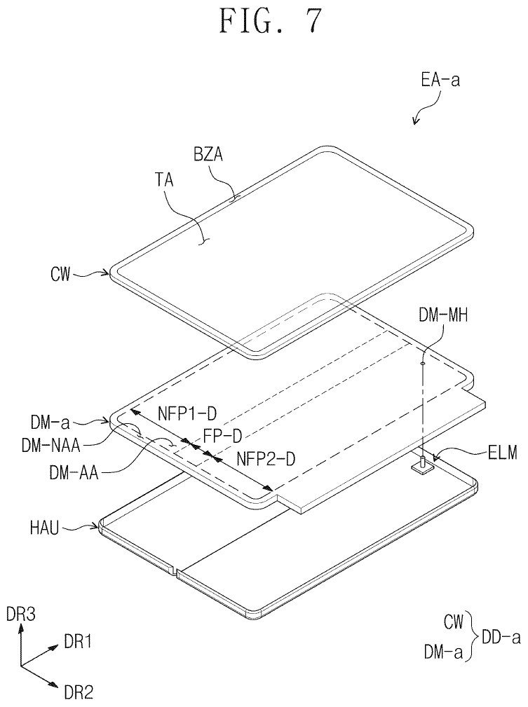

FIGS. 6A to 7 are views illustrating an electronic apparatus EA-a according to an embodiment of the inventive concept. Hereinafter, with regard to the descriptions of FIGS. 6A to 7, to the extent that an element is not described in detail with respect to this figure, it may be understood that the element is at least similar to a corresponding element that has been described elsewhere within the present disclosure.

The electronic apparatus EA-a illustrated in FIGS. 6A to 7 may be an apparatus which is foldable with respect to at least one among folding axes FX1 and FX2. FIG. 6A is a perspective view illustrating the electronic apparatus EA-a in an unfolded state.

The electronic apparatus EA-a may include a first display surface FS and a second display surface RS. The first display surface FS may include a first display region F-DA, a first non-display region F-NDA, and a sub-region MH-a. The second display surface RS may be defined as a surface opposed to at least a portion of the first display surface FS. For example, the second display surface RS may be defined as a portion of a rear surface of the electronic apparatus EA-a.

The first display region F-DA may be activated in response to an electrical signal. The first display region F-DA may be a region in which an image IM may be displayed and various types of external inputs may be detected. The first non-display region F-NDA may be adjacent to the first display region F-DA. The light transmittance of the first non-display region F-NDA may be less than the light transmittance of the first display region F-DA. The first non-display region F-NDA may have a predetermined color. The first non-display region F-NDA may surround the first display region F-DA. Accordingly, a shape of the first display region F-DA may be substantially defined by the first non-display region F-NDA. However, this is presented as an example, and the first non-display region F-NDA may be disposed adjacent to only one side of the first display region F-DA or may be omitted.

The sub-region MH-a may detect an external subject received via the display surfaces FS and RS, or provide a sound signal, such as voice, to the outside via the display surfaces FS and RS. An optical signal such as visible light or infrared light may move to the sub-region MH-a.

Various electronic modules ELM (see FIG. 7) may be disposed so as to correspond to the sub-region MH-a. For example, the electronic module ELM (see FIG. 7) may include at least one of a camera, a speaker, a light detection sensor, and a heat detection sensor. The electronic apparatus EA-a may include the electronic module ELM (see FIG. 7) which captures an external image by using visible light passing through the sub-region MH-a or determines whether an external object is approaching by using infrared light.

The sub-region MH-a may be disposed within the first display region F-DA. However, this is presented as an example, and an arrangement of the sub-region MH-a is not necessarily limited to any one embodiment. For example, the sub-region MH-a might not only be surrounded by the first non-display region F-NDA but also be surrounded by the first display region F-DA and the first non-display region F-NDA. FIG. 6A, etc., illustrate one sub-region MH-a, but the sub-region MH-a may also be provided in plural.

The electronic apparatus EA-a may include at least one folding region FA, and a plurality of non-folding regions NFA1 and NFA2 extending from the folding region FA. For example, a first non-folding region NFA1, the folding region FA, and a second non-folding region NFA2 may be defined along the second direction DR2. The electronic apparatus EA-a may include the first non-folding region NFA1 and the second non-folding region NFA2 which are spaced apart from each other in the second direction DR2 with the folding region FA therebetween. For example, the first non-folding region NFA1 may be disposed on one side of the folding region FA along the second direction DR2, and the second non-folding region NFA2 may be disposed on the other side of the folding region FA along the second direction DR2.

FIG. 6A, etc., illustrate the electronic apparatus EA-a, of an embodiment, including one folding region FA, but an embodiment of the inventive concept is not necessarily limited thereto. A plurality of folding regions may be defined in the electronic apparatus EA-a. For example, the electronic apparatus, according to an embodiment, may include two or more folding regions, and may also include three or more non-folding regions disposed with each of the folding regions therebetween.

FIG. 6B is a perspective view illustrating a folding operation of the electronic apparatus EA-a illustrated in FIG. 6A. FIG. 6C is a plan view illustrating a state in which the electronic apparatus EA-a illustrated in FIG. 6A is folded. FIG. 6D is a perspective view illustrating a folding operation of the electronic apparatus EA-a illustrated in FIG. 6A.

Referring to FIG. 6B, the electronic apparatus EA-a may be folded with respect to a first folding axis FX1 extending in the first direction DR1. In a folded state of the electronic apparatus EA-a, the folding region FA may have a predetermined curvature and radius of a curvature. The electronic apparatus EA-a may be folded with respect to the first folding axis FX1, and be changed into an in-folded state such that the first non-folding region NFA1 and the second non-folding region NFA2 face each other and the first display surface FS is not exposed to the outside.

FIG. 6C may be a plan view illustrating a state in which the electronic apparatus EA-a is in-folded. Referring to FIG. 6C, in an in-folded state of the electronic apparatus EA-a, the second display surface RS may be viewed by a user. In this case, the second display surface RS may include a second display region R-DA which displays an image. The second display region R-DA may be activated in response to an electrical signal. The second display region R-DA may be a region in which an image may be displayed and various types of external inputs may be detected.

Additionally, the second display surface RS may include a second non-display region R-NDA. The second non-display region R-NDA may be adjacent to the second display region R-DA. The light transmittance of the second non-display region R-NDA may be less than the light transmittance of the second display region R-DA. The second non-display region R-NDA may have a predetermined color. The second non-display region R-NDA may surround the second display region R-DA. The electronic apparatus EA-a may further include, also in the second display surface RS, a sub-region in which an electronic module including various components is disposed, and is not necessarily limited to any one embodiment.

Referring to FIG. 6D, the electronic apparatus EA-a may be folded with respect to a second folding axis FX2 extending in the first direction DR1. The electronic apparatus EA-a may be folded with respect to the second folding axis FX2, and be changed into an out-folded state such that the first display surface FS is exposed to the outside. The electronic apparatus EA-a, according to an embodiment, may be configured to repeatedly perform an in-folding or out-folding operation from an unfolding operation and vice versa, but an embodiment of the inventive concept is not necessarily limited thereto.

FIGS. 6A to 6D exemplarily illustrate that the electronic apparatus EA-a is folded with respect to one folding axis FX1 or FX2, but in the electronic, apparatus according to an embodiment, the number of folding axes and the number of non-folding regions corresponding to the number of folding axes are not necessarily limited thereto. For example, the electronic apparatus EA-a may be folded with respect to a plurality of folding axes such that respective portions of the first display surface FS and the second display surface RS face each other. Also, it is illustrated that the first and second folding axes FX1 and FX2 are parallel to a long side of the electronic apparatus EA-a, but an embodiment of the inventive concept is not necessarily limited thereto. The first and second folding axes FX1 and FX2 may be parallel to a short side of the electronic apparatus EA-a.

In a state in which the electronic apparatus EA-a is folded as illustrated in FIG. 6C, the first non-folding region NFA1 and the second non-folding region NFA2 may be defined as portions having the display surfaces FS and RS in a plane defined by the first direction axis DR1 and the second direction axis DR2, and the folding region FA may be defined as a region between the first non-folding region NFA1 and the second non-folding region NFA2. The folding region FA may have a curved portion which is curved so as to have a predetermined curvature in a folded state.

FIG. 7 is an exploded perspective view of the electronic apparatus EA-a illustrated in FIG. 6A. Referring to FIG. 7, the electronic apparatus EA-a may include a display device DD-a and an electronic module ELM. The electronic apparatus EA-a may further include a housing HAU. The display device DD-a may include a display module DM-a and a cover window CW disposed on the display module DM-a.

The display module DM-a may include a folding display part FP-D and non-folding display parts NFP1-D and NFP2-D. The folding display part FP-D may be a portion corresponding to the folding region FA (see FIG. 6A), and the non-folding display parts NFP1-D and NFP2-D may be portions corresponding to the non-folding regions NFA1 and NFA2 (see FIG. 6A).

The folding display part FP-D may correspond to a portion which is folded with respect to the folding axes FX1 and FX2 (see FIGS. 6B and 6D). The non-folding display parts NFP1-D and NFP2-D may include a first non-folding display part NFP1-D and a second non-folding display part NFP2-D. The first non-folding display part NFP1-D and the second non-folding display part NFP2-D may be spaced apart from each other in the second direction DR2 with the folding display part FP-D therebetween. The first non-folding display part NFP1-D may be a portion corresponding to the first non-folding region NFA1 (see FIG. 6A). The second non-folding display part NFP2-D may be a portion corresponding to the second non-folding region NFA2 (see FIG. 6A).

The electronic apparatus EA-a may further include a lower module disposed below the display module DM-a. For example, the lower module may include a support layer, a cushion layer, a shielding layer, etc. The support layer may be a thin-film metal substrate. The cushion layer may include an elastomer such as a sponge, a foam, or a urethane resin. The shielding layer may be an electromagnetic wave shielding layer or a heat dissipation layer. However, this is presented as an example, and components included in the lower module may vary according to a size, a shape or operating characteristics, etc., of the electronic apparatus EA-a.

In an embodiment, an electronic apparatus may include a display device and an electronic module. The display device may include a cover window disposed on a display panel. The cover window may include an anti-reflection layer and a nitrogen-containing layer disposed on the anti-reflection layer. The anti-reflection layer may include a high-refractive-index layer and a low-refractive-index layer disposed on the high-refractive-index layer, and the nitrogen-containing layer may be directly disposed on the low-refractive-index layer. The nitrogen-containing layer may be formed by performing a nitrogen treatment on a surface of the low-refractive-index layer, and have a thickness within a range of about 0.5 nm to about 5 nm, inclusive. Therefore, the nitrogen-containing layer may improve hardness and scratch resistance while maintaining excellent reflectance. The cover window, according to an embodiment, including the nitrogen-containing layer may have improved hardness and scratch resistance while exhibiting excellent reflectance. In an embodiment, the display device including the cover window and the electronic apparatus including the same may have improved hardness and scratch resistance while exhibiting excellent reflectance.

A cover window, according to an embodiment, includes a nitrogen-containing layer, and may thus achieve improved hardness and scratch resistance properties while exhibiting excellent reflectance.

A display device, according to an embodiment, and an electronic apparatus including the display device include a cover window including a nitrogen-containing layer, and may thus achieve improved hardness and scratch resistance properties while exhibiting excellent reflectance.

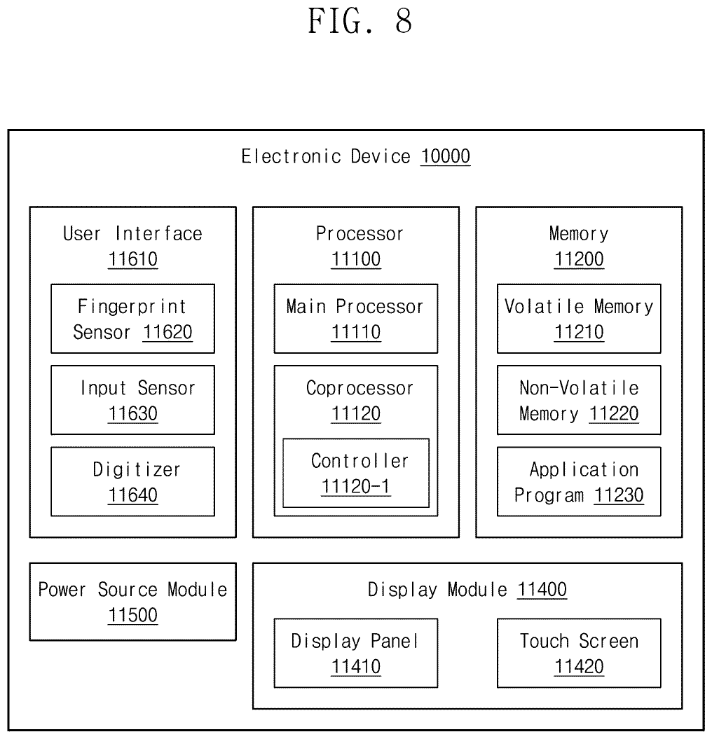

FIG. 8 is a diagram illustrating an electronic device according to an embodiment of the present invention. Referring to FIG. 8, the electronic device 1000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

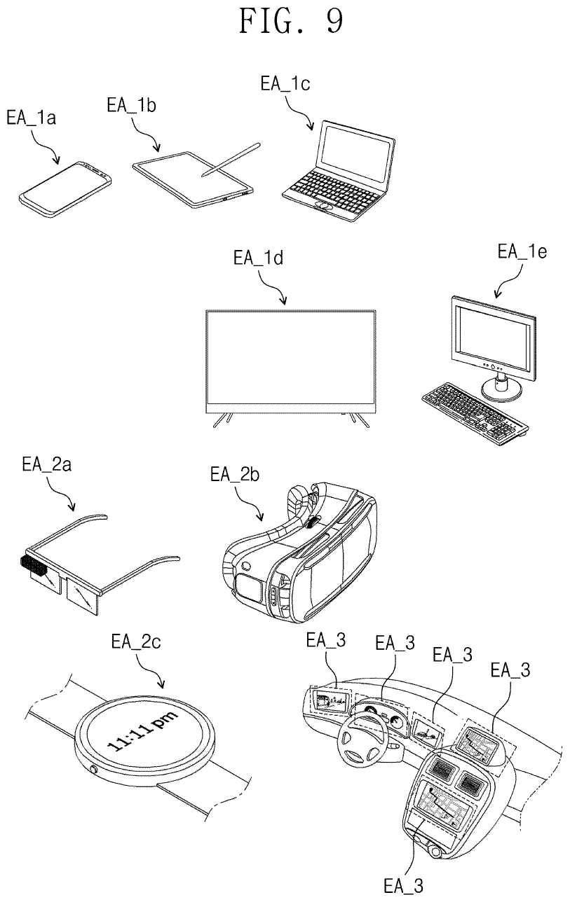

FIG. 9 is a schematic view illustrating electronic apparatuses according to various embodiments. Referring to FIG. 9, an electronic apparatus EA including the display device DD (see FIG. 2) according to an embodiment may include not only electronic apparatuses for displaying images, e.g., a smartphone EA_1a, a tablet computer (PC) EA_1b, a laptop computer EA_1c, TV EA_1d, and a monitor for a desk computer EA_1e, but also wearable electronic apparatuses including display devices, e.g., smart glasses EA_2a, a head mounted display EA_2b, and a smart watch EA_2c, and vehicle electronic apparatuses EA_3 including display devices, e.g., a vehicle instrument panel, a center fascia, a center information display (CID) disposed on a dashboard, and a room mirror display.

Although the embodiments of the inventive concept have been described, it is understood that the inventive concept should not necessarily be limited to these embodiments but various changes and modifications can be made by one ordinary skilled in the art within the spirit and scope of the inventive concept.

What is claimed is:

1. A cover window, comprising:
a base layer;
an anti-reflection layer disposed on the base layer and including a high-refractive-index layer and a low-refractive-index layer disposed on the high-refractive-index layer; and
a nitrogen-containing layer disposed on the anti-reflection layer and having a thickness within a range of about 0.5 nm to about 5 nm, inclusive.

2. The cover window of claim 1, wherein a refractive index of the nitrogen-containing layer is greater than a refractive index of the low-refractive-index layer and the refractive index of the nitrogen-containing layer is less than a refractive index of the high-refractive-index layer.

3. The cover window of claim 1, wherein the nitrogen-containing layer is directly disposed on the low-refractive-index layer.

4. The cover window of claim 1, wherein a thickness of the nitrogen-containing layer is less than each of a thickness of the high-refractive-index layer, and a thickness of the low-refractive-index layer.

5. The cover window of claim 1, wherein the low-refractive-index layer comprises at least one of silicon oxide, aluminum oxide, and silicon oxynitride.

6. The cover window of claim 1, wherein nitrogen of the nitrogen-containing layer is chemically bonded to a material of the low-refractive-index layer.

7. The cover window of claim 1, further comprising a functional layer disposed on the nitrogen-containing layer,
wherein the functional layer includes at least one of an antistatic agent, a hard coating agent, and an anti-fingerprint agent.

8. The cover window of claim 7, wherein a thickness of the nitrogen-containing layer is less than a thickness of the functional layer.

9. The cover window of claim 1, wherein the high-refractive-index layer and the low-refractive-index layer are each provided in plural, and
wherein members of the plurality of high-refractive-index layers and members of the plurality of low-refractive-index layers are alternately disposed with respect to one another.

10. A display device, comprising:
a display panel including a light-emitting element; and
a cover window disposed on the display panel,
wherein the cover window includes
a base layer,
an anti-reflection layer disposed on the base layer and including a high-refractive-index layer and a low-refractive-index layer disposed on the high-refractive-index layer, and
a nitrogen-containing layer disposed on the anti-reflection layer and having a thickness within a range of about 0.5 nm to about 5 nm, inclusive.

11. The display device of claim 10, wherein a refractive index of the nitrogen-containing layer is greater than a refractive index of the low-refractive-index layer and the refractive index of the nitrogen-containing layer is less than a refractive index of the high-refractive-index layer.

12. The display device of claim 10, wherein the nitrogen-containing layer is directly disposed on the low-refractive-index layer.

13. The display device of claim 10, wherein a thickness of the nitrogen-containing layer is less than each of a thickness of the high-refractive-index layer and a thickness of the low-refractive-index layer.

14. The display device of claim 10, wherein the low-refractive-index layer comprises at least one of silicon oxide, aluminum oxide, and silicon oxynitride.

15. The display device of claim 10, wherein the high-refractive-index layer and the low-refractive-index layer are each provided in plural, and
wherein members of the plurality of high-refractive-index layers and members of the plurality of low-refractive-index layers are alternately disposed with respect to one another.

16. The display device of claim 10, wherein the light-emitting element comprises:
a first electrode;
a second electrode disposed on the first electrode; and
a light-emitting layer disposed between the first electrode and the second electrode.

17. An electronic apparatus, comprising:
a display device having a module region defined therein; and
an electronic module disposed on the module region,
wherein the display device includes:
a display panel including a light-emitting element, and
a cover window disposed on the display panel, and
wherein the cover window includes:
a base layer,
an anti-reflection layer disposed on the base layer and including a high-refractive-index layer and a low-refractive-index layer disposed on the high-refractive-index layer, and
a nitrogen-containing layer disposed on the anti-reflection layer and having a thickness within a range of about 0.5 nm to about 5 nm, inclusive.

18. The electronic apparatus of claim 17, wherein a refractive index of the nitrogen-containing layer is greater than a refractive index of the low-refractive-index layer, and is less than a refractive index of the high-refractive-index layer, and a thickness of the nitrogen-containing layer is less than a thickness of the high-refractive-index layer and a thickness of the low-refractive-index layer.

19. The electronic apparatus of claim 17, wherein the nitrogen-containing layer is directly disposed on the low-refractive-index layer.

20. The electronic apparatus of claim 17, wherein the low-refractive-index layer comprises at least one of silicon oxide, aluminum oxide, and silicon oxynitride.
